(19) United States
(12) Patent Application Publication
(10) Pub. No.: US 2015/0270440 A1
(43) Pub. Date: Sep. 24, 2015

(54) SEMICONDUCTOR LIGHT EMITTING ELEMENT AND METHOD FOR MANUFACTURING SAME

(71) Applicant: Kabushiki Kaisha Toshiba, Minato-ku (JP)

(72) Inventors: Shigeya KIMURA, Yokohama (JP); Shinya Nunoue, Ichikawa (JP)

(73) Assignee: Kabushiki Kaisha Toshiba, Minato-ku (JP)

(21) Appl. No.: 14/658,418

(22) Filed: Mar. 16, 2015

(30) Foreign Application Priority Data
Mar. 24, 2014 (JP) 2014-060634

(51) Int. Cl. H01L 33/18; H01L 33/00; H01L 33/32

(52) U.S. Cl. CPC H01L 33/18; H01L 33/325; H01L 33/0075

(57) ABSTRACT

According to one embodiment, a semiconductor light emitting element includes a first semiconductor layer, a second semiconductor layer, and a light emitting unit. The first semiconductor layer includes an n-type impurity having a first concentration. The second semiconductor layer includes a p-type impurity. The light emitting unit is provided between the first and second semiconductor layers. The light emitting unit includes a first barrier layer, a second barrier layer provided between the first barrier layer and the second semiconductor layer, a third barrier layer provided between the second barrier layer and the second semiconductor layer, a first well layer provided between the first and second barrier layers, and a second well layer provided between the second and third barrier layers. A plane including a boundary between the first barrier layer and the first well layer intersects a plane including a (0001) plane of the first semiconductor layer.

### CROSS-REFERENCE TO RELATED APPLICATIONS

This application is based upon and claims the benefit of priority from Japanese Patent Application No. 2014-060634, filed on Mar. 24, 2014; the entire contents of which are incorporated herein by reference.

### FIELD

Embodiments described herein relate generally to a semiconductor light emitting element and a method for manufacturing the same.

### BACKGROUND

Group III-V nitride compound semiconductors such as gallium nitride (GaN), etc., are being applied to light emitting diodes (LEDs), laser diodes (LDs), etc. It is desirable to increase the luminous efficiency of such semiconductor light emitting elements.

### BRIEF DESCRIPTION OF THE DRAWINGS

FIG. 1A and FIG. 1B are schematic cross-sectional views showing a semiconductor light emitting element according to a first embodiment;

FIG. 2 is a graph showing characteristics of the semiconductor light emitting element;

FIG. 3 is a graph showing characteristics of the semiconductor light emitting element;

FIG. 4A to FIG. 4F are graphs showing characteristics of the semiconductor light emitting element;

FIG. 5 is a graph showing characteristics of the semiconductor light emitting element;

FIG. 6 is a graph showing characteristics of the semiconductor light emitting element;

FIG. 7 is a graph showing characteristics of the semiconductor light emitting element;

FIG. 8 is a graph showing characteristics of the semiconductor light emitting element;

FIG. 9 is a graph showing characteristics of the semiconductor light emitting element; and

FIG. 10 is a flowchart showing a method for manufacturing the semiconductor light emitting element according to the first embodiment.

### DETAILED DESCRIPTION

According to one embodiment, a semiconductor light emitting element includes a first semiconductor layer, a second semiconductor layer, and a light emitting unit. The first semiconductor layer includes an n-type impurity having a first concentration. The second semiconductor layer includes a p-type impurity. The light emitting unit is provided between the first semiconductor layer and the second semiconductor layer. The light emitting unit includes a first barrier layer, a second barrier layer provided between the first barrier layer and the second semiconductor layer, the second barrier layer including an n-type impurity having a second concentration higher than the first concentration, a third barrier layer provided between the second barrier layer and the second semiconductor layer, a first well layer provided between the first barrier layer and the second barrier layer, and a second well layer provided between the second barrier layer and the third barrier layer. A plane including a boundary between the first barrier layer and the first well layer intersects a plane including a (0001) plane of the first semiconductor layer.

Various embodiments will be described hereinafter with reference to the accompanying drawings.

The drawings are schematic or conceptual; and the relationships between the thicknesses and widths of portions, the proportional coefficients of sizes between portions, etc., are not necessarily the same as the actual values thereof. Further, the dimensions and/or the proportional coefficients may be illustrated differently between the drawings, even for the same portions.

In the drawings and the specification of the application, components similar to those described in regard to a drawing thereinabove are marked with like reference numerals, and a detailed description is omitted as appropriate.

### First Embodiment

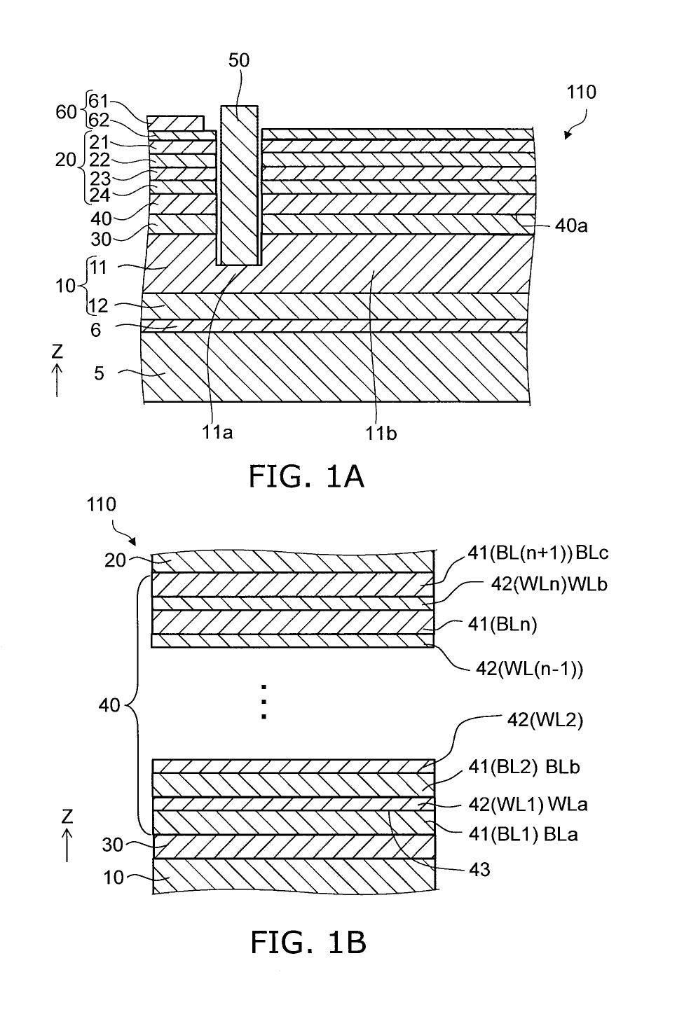

FIG. 1A and FIG. 1B are schematic cross-sectional views showing a semiconductor light emitting element according to a first embodiment.

FIG. 1A is a schematic cross-sectional view illustrating the configuration of the semiconductor light emitting element according to the first embodiment.

FIG. 1B is a schematic cross-sectional view illustrating the configuration of a portion of the semiconductor light emitting element according to the first embodiment.

As shown in FIG. 1A, the semiconductor light emitting element 110 according to the embodiment includes a first semiconductor layer 10, a second semiconductor layer 20, a stacked body 30, a light emitting unit 40, a first electrode 50, and a second electrode 60. The stacked body 30 is provided between the light emitting unit 40 and the first semiconductor layer 10. The light emitting unit 40 is provided between the first semiconductor layer 10 and the second semiconductor layer 20. The light emitting unit 40 has a major surface 40a. The direction from the first semiconductor layer 10 toward the second semiconductor layer 20 is taken as a Z-axis direction.

A buffer layer 6 is provided on a substrate 5. The first semiconductor layer 10, the stacked body 30, the light emitting unit 40, and the second semiconductor layer 20 are provided in order in the Z-axis direction on the buffer layer 6. Such a stacked structure is formed by epitaxial growth. For example, the epitaxial growth is performed by metal organic chemical vapor deposition (MOCVD), molecular beam epitaxy (MBE), or halide vapor phase epitaxy (HVPE). The substrate 5 may be removed after forming such a stacked structure.

Generally, for a compound semiconductor, the plane orientation of the crystal structure is expressed using four-index notation (hexagonal indices). The basic vector c extends in the (0001) direction; and the axis of this direction is called the c-axis. The plane perpendicular to the c-axis is called the c-plane (a polar plane). The c-plane (the polar plane) also is called the (0001) plane. In such a crystal structure, crystal plane orientations other than the c-plane also exist. For example, the m-plane and the a-plane are non-polar planes parallel to the c-axis direction. The r-plane is a semi-polar plane tilted with respect to the c-axis direction.

c-plane growth means the epitaxial growth occurring in a direction perpendicular to the c-plane. m-plane growth, a-plane growth, and r-plane growth mean the epitaxial growth occurring in directions perpendicular to the m-plane, the a-plane, and the r-plane, respectively.

In the case where the semiconductor light emitting element 110 is formed using a stacked structure formed by c-plane growth, spontaneous polarization occurs due to the shift of the positions of the Ga atoms and the N atoms in the c-axis direction in the c-plane. In the InGaN included in the light emitting unit 40, piezoelectric polarization occurs due to strain. Due to the piezoelectric polarization, the probability of radiative recombination of the carriers in the light emitting unit 40 decreases; and the internal quantum efficiency decreases. An increase of the power consumption and a decrease of the luminous efficiency are caused in a light emitting element such as a light emitting diode, etc. As the injected carrier density increases, the light emission wavelength changes because screening of the piezoelectric field occurs.

In the embodiment, for example, a stacked structure is formed using a non-polar plane (e.g., the m-plane or the a-plane) or a semi-polar plane (e.g., the r-plane) as the growth surface. By forming the stacked structure in which the non-polar plane or the semi-polar plane is used as the growth surface, the effects of the piezoelectric polarization in the Z-axis direction of the light emitting unit 40 can be reduced. To use the non-polar plane or the semi-polar plane as the growth surface, the stacked structure can be formed at a tilt angle tilted at any angle with respect to the c-plane. For example, the major surface 40a of the light emitting unit 40 is tilted from the c-plane (the polar plane) not less than 15 degrees and not more than 165 degrees. For tilt angles 15 degrees or more, the effects of the semi-polar plane become large; and the effects of the piezoelectric polarization can be reduced further.

The substrate 5 includes, for example, a sapphire substrate (an m-plane or r-plane sapphire substrate). A substrate including Si, GaN, SiC, or ZnO may be used as the substrate 5.

For example, a layer including at least one of an AlN layer, an AlGaN layer, or a GaN layer is used as the buffer layer 6.

The first semiconductor layer 10 includes a nitride semiconductor. The first semiconductor layer 10 is, for example, an n-type semiconductor layer. For example, the n-type impurity of the first semiconductor layer 10 has any concentration (a first concentration). For example, Si is used as the n-type impurity. Ge or Sn may be used as the n-type impurity.

The first semiconductor layer 10 includes a first n-side layer 11 and a second n-side layer 12. The first n-side layer 11 is disposed between the second n-side layer 12 and the stacked body 30. For example, the first n-side layer 11 is an n-type GaN contact layer. For example, the second n-side layer 12 is an undoped GaN foundation layer.

The first n-side layer 11 includes a first portion 11a and a second portion 11b. The impurity concentration of the first n-side layer 11 is higher than the impurity concentration of the second n-side layer 12.

The second semiconductor layer 20 includes a nitride semiconductor. The second semiconductor layer 20 is, for example, a p-type semiconductor layer. The second semiconductor layer 20 includes, for example, a p-type impurity. For example, Mg is used as the p-type impurity. Zn may be used as the p-type impurity.

The second semiconductor layer 20 includes, for example, a first p-side layer 21, a second p-side layer 22, a third p-side layer 23, and a fourth p-side layer 24. The second p-side layer 22 is provided between the first p-side layer 21 and the light emitting unit 40. The third p-side layer 23 is provided between the second p-side layer 22 and the light emitting unit 40. The fourth p-side layer 24 is provided between the third p-side layer 23 and the light emitting unit 40.

The first p-side layer 21 is, for example, a contact layer. The first p-side layer 21 includes, for example, p-type GaN. The second p-side layer 22 includes, for example, p-type GaN. The impurity concentration of the first p-side layer 21 is higher than the impurity concentration of the second p-side layer 22.

The third p-side layer 23 includes, for example, p-type AlGaN. The fourth p-side layer 24 includes, for example, p-type AlGaN. The third p-side layer 23 and the fourth p-side layer 24 function as layers that suppress the overflow of electrons.

The stacked body 30 is, for example, a superlattice layer. For example, the stacked body 30 includes multiple layers. A layer including GaN and a layer including InGaN are stacked alternately along the Z-axis direction as the stacked body 30. The stacked body 30 is provided as necessary and may be omitted.

The light emitting unit 40 is, for example, an active layer. The light emitting unit 40 has, for example, a multiple quantum well (MQW) structure. The light emitting unit 40 has a structure in which multiple barrier layers 41 and multiple well layers 42 are repeatedly stacked alternately. An example of the configuration of the barrier layers 41 and the well layers 42 is described below.

The first electrode 50 includes, for example, a stacked film of a Ti film/Pt film/Au film. The thickness of the Ti film is, for example, about 0.05 micrometers (μm). The thickness of the Pt film is, for example, about 0.05 μm. The thickness of the Au film is, for example, about 1.0 μm.

The first electrode 50 is electrically connected to the first semiconductor layer 10. For example, a trench is made in the second semiconductor layer 20, the stacked body 30, and the light emitting unit 40. The first electrode 50 is connected to the first n-side layer 11 at the bottom surface of the trench. The second portion 11b is arranged with the first portion 11a in a plane perpendicular to the Z-axis direction. The first electrode 50 is connected to the first portion 11a. The light emitting unit 40 is provided between the second portion 11b and the second semiconductor layer 20.

The second electrode 60 includes a first conductive unit 61 and a second conductive unit 62. The second conductive unit 62 is provided between the first conductive unit 61 and the second semiconductor layer 20. The first conductive unit 61 is electrically connected to the second conductive unit 62. The first conductive unit 61 contacts a portion of the second conductive unit 62. The second conductive unit 62 contacts the second semiconductor layer 20.

The first conductive unit 61 includes, for example, a stacked film of a Ni film/Au film. The thickness of the Ni film is, for example, about 0.05 μm. The thickness of the Au film is, for example, about 1.0 μm.

The second conductive unit 62 includes, for example, an oxide including at least one element selected from In, Sn, Zn, and Ti. The second conductive unit 62 includes, for example, ITO (Indium Tin Oxide). The thickness of the second conductive unit 62 is, for example, about 0.2 μm.

A current flows in the light emitting unit 40 by applying a voltage between the first electrode 50 and the second electrode via the first semiconductor layer 10 and the second semiconductor layer 20. Light is emitted from the light emitting unit 40 when the current flows in the light emitting unit 40. The peak wavelength of the light that is emitted is, for example, not less than 370 nanometers and not more than 650 nanometers.

The light that is emitted from the light emitting unit 40 is emitted to the outside from the second semiconductor layer 20 side. The second semiconductor layer 20 has a light emitting surface. The light may be emitted to the outside from the first semiconductor layer 10 side.

The semiconductor light emitting element 110 according to the embodiment is, for example, a light emitting diode.

As shown in FIG. 1B, the light emitting unit 40 includes the barrier layer 41, and the well layer 42 stacked with the barrier layer 41. In the light emitting unit 40, multiple barrier layers 41 are provided; and multiple well layers 42 are provided. The well layers 42 are provided respectively in the spaces between the multiple barrier layers 41.

The barrier layer 41 and the well layer 42 include nitride semiconductors. The well layer 42 includes a nitride semiconductor including In.

The barrier layer 41 includes, for example, In_{b}Ga_{1-b}N (0≦b<1). The thickness of the barrier layer 41 is, for example, not less than 3 nanometers (nm) and not more than 20 nm. The well layer 42 includes, for example, In_{w}Ga_{1-w}N (0<w<1). The thickness of the well layer 42 is, for example, not less than 2 nm and not more than 10 nm.

The In composition ratio w of the well layer 42 is higher than the In composition ratio b of the barrier layer 41. b<w. The In composition ratio b of the barrier layer 41 may be 0. For example, the barrier layer 41 may be GaN. The In composition ratio w of the well layer 42 is greater than 0; and the well layer 42 includes InGaN.

In the case where the barrier layer 41 includes In, the composition ratio b of In in the barrier layer 41 is lower than the composition ratio w of In in the well layer 42. The bandgap energy of the well layer 42 is smaller than the bandgap energy of the barrier layer 41. The barrier layer 41 and the well layer 42 may include traces of Al, etc.

The light emitting unit 40 includes, for example, n+1 barrier layers 41 and n well layers 42. n is an integer not less than 2. The barrier layer BL(n+1) is provided between the barrier layer BLn and the second semiconductor layer 20. The well layer WLn is provided between the well layer WL(n−1) and the second semiconductor layer 20. The barrier layer BL1 is provided between the first semiconductor layer 10 and the well layer WL1. The well layer WLn is provided between the barrier layer BLn and the barrier layer BL(n+1). The barrier layer BL(n+1) is provided between the well layer WLn and the second semiconductor layer 20. The thicknesses of the multiple barrier layers 41 may be different from each other. For example, the thickness of the barrier layer BL(n+1) may be the same as or different from the thicknesses of the other barrier layers 41.

For the n+1 barrier layers 41, for example, the barrier layer BL(n+1) contacts the second semiconductor layer 20. The barrier layer BL(n+1) of the n+1 barrier layers 41 is most proximal to the second semiconductor layer 20. The barrier layer BLn is second most proximal to the second semiconductor layer 20. The barrier layer BL(n−1) is third most proximal to the second semiconductor layer 20. The barrier layer BL1 is the (n+1)th most proximal to the second semiconductor layer 20.

For example, the barrier layer BL1 corresponds to a first barrier layer BLa. For example, the barrier layers BL2 to BLn correspond to second barrier layers BLb. For example, the barrier layer BL(n+1) corresponds to a third barrier layer BLc.

The well layer WLn of the n well layers 42 is most proximal to the second semiconductor layer 20. The well layer WL(n−1) is second most proximal to the second semiconductor layer 20. The well layer WL1 is the nth most proximal to the second semiconductor layer 20.

For example, the well layer WL1 corresponds to a first well layer WLa. For example, the well layer WLn corresponds to a second well layer WLb.

In the embodiment, the plane that includes a boundary 43 between the first barrier layer BLa and the first well layer WLa intersects the plane of the first semiconductor layer 10 including the (0001) plane. For example, the boundary 43 is tilted with respect to the (0001) plane. The angle between the (0001) plane and the plane including the boundary 43 is, for example, not less than 15 degrees and not more than 165 degrees.

The angle between the (0001) plane and the plane including the boundary 43 can be known from, for example, X-ray analysis. The angle also can be known from, for example, a TEM (transmission electron microscope) image, etc.

In the case where n+1 barrier layers 41 and n well layers 42 are provided as the light emitting unit 40, the n-type impurity concentration of at least one barrier layer of the barrier layers BL2 to BLn is not less than the n-type impurity concentration of the first semiconductor layer 10. The n-type impurity of the second barrier layer BLb has a second concentration that is higher than the first concentration of the first semiconductor layer 10. In the multiple quantum well structure that is non-polar or semi-polar, by setting such concentrations, electrons are supplied to the well layer WLn most proximal to the second semiconductor layer 20. The level of the contribution to the light emission by the well layer WLn is large. Thereby, a semiconductor light emitting element having high luminous efficiency is provided.

The investigation results that formed the basis for the discovery of conditions such as those recited above will now be described.

In the following example, the stacked structure that includes the first semiconductor layer 10, the stacked body 30, the light emitting unit 40, and the second semiconductor layer 20 is stacked in the Z-axis direction based on the semi-polar plane. The light emitting unit 40 includes the barrier layer 41, and the well layer 42 that is stacked with the barrier layer 41. The number of barrier layers 41 is 9 (n=8); and the number of well layers 42 is 8. The well layers 42 are provided respectively in the spaces between the barrier layers 41. The characteristics of such a stacked structure are evaluated by simulation.

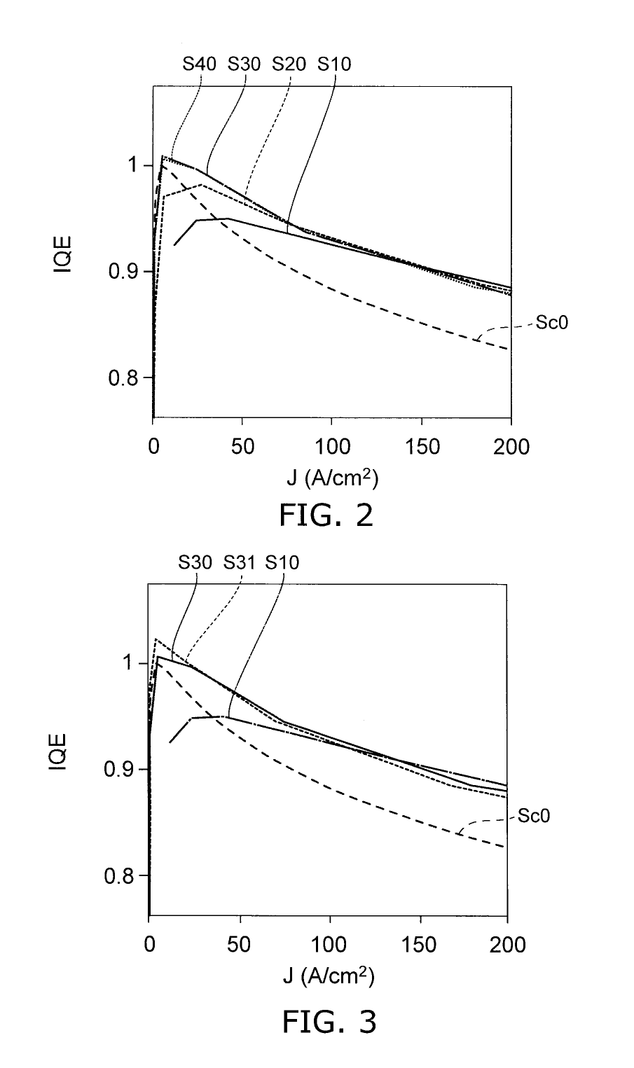

FIG. 2 is a graph illustrating characteristics of the semiconductor light emitting element.

FIG. 2 illustrates the simulation results of the characteristics of the semiconductor light emitting element for five types of conditions described below. In FIG. 2, the horizontal axis is a current density J (A/cm²) injected into the light emitting unit 40. The vertical axis is an internal quantum efficiency IQE. In the following description, the concentration of Si for “the case where Si is not doped” is 1.0×10¹⁶/cm³.

For a condition S10 illustrated in FIG. 2, none of the multiple barrier layers 41 are doped with Si. For a condition S20, the Si concentration of the barrier layer BL2 is higher than the Si concentration of the first semiconductor layer 10. For a condition S30, the Si concentration of the barrier layer BL8 is higher than the Si concentration of the first semiconductor layer 10. For a condition S40, the Si concentrations of the barrier layers BL2 to BL8 are higher than the Si concentration of the first semiconductor layer 10. The barrier layers of the multiple barrier layers 41 other than those noted are not doped with Si.

For a condition Sc0, none of the multiple barrier layers 41 of the stacked structure of the c-plane (the polar plane) are doped with Si.

In FIG. 2, the internal quantum efficiency IQE is a relative value for which the maximum value of the internal quantum efficiency for the condition Sc0 is set to 1. In the example, the Si concentration of the first semiconductor layer 10 is 2.0×10¹⁸ per cubic centimeter (/cm³). In the case where the Si concentration of the barrier layer 41 is higher than the Si concentration of the first semiconductor layer 10, the Si concentration of the barrier layer 41 is 5.0×10¹⁸/cm³. The thickness of each of the multiple barrier layers is 5.0 nm. The thickness of each of the multiple well layers is 3.5 nm.

The internal quantum efficiency IQE is high for the conditions S20, S30, and S40 compared to the condition S10 (none of the multiple barrier layers 41 being doped with Si).

The internal quantum efficiency IQE for the condition S30 (the Si concentration of the barrier layer BL8 positioned on the second semiconductor layer 20 side being higher than the Si of the first semiconductor layer 10) is higher than the internal quantum efficiency IQE for the condition S20 (the Si concentration of the barrier layer BL2 positioned on the first semiconductor layer 10 side being higher than the Si concentration of the first semiconductor layer 10).

The internal quantum efficiency IQE for the condition S30 (the Si concentration of the barrier layer BL8 being high) is about the same as the internal quantum efficiency IQE for the condition S40 (the Si concentration of the barrier layers BL2 to BL8 being high).

Because the example shown in FIG. 2 is the result of a band simulation, the decrease of the crystal quality due to increasing the Si concentration is not considered. Crystal defects occur easily when the Si concentration increases excessively. Therefore, it is considered that the condition S30 (the Si concentration of the barrier layer BL8 being higher than the Si concentration of the first semiconductor layer 10) is effective for increasing the internal quantum efficiency IQE.

FIG. 3 is a graph illustrating characteristics of the semiconductor light emitting element.

FIG. 3 shows simulation results of different Si concentrations for the condition S30 (the Si concentration of the barrier layer BL8 being higher than the Si concentration of the first semiconductor layer 10) illustrated in FIG. 2. The horizontal axis is the current density J (A/cm²) injected into the light emitting unit 40; and the vertical axis is the internal quantum efficiency IQE.

The condition S30 shown in FIG. 3 is similar to that of FIG. 2; and the Si concentration of the barrier layer BL8 is 5.0×10¹⁸/cm³. For a condition S31, the Si concentration of the barrier layer BL8 is 1.0×10¹⁹/cm³. FIG. 3 also shows the results for the condition S10 and the condition Sc0 shown in FIG. 2. In such a case as well, the Si concentration of the barrier layer 41 when not doped with Si is 1.0×10¹⁶/cm³. The Si concentration of the first semiconductor layer 10 is 2.0×10¹⁸/cm³.

From FIG. 2 and FIG. 3, it is considered that the condition S30 (the Si concentration of the barrier layer BL8 being 5.0×10¹⁸/cm³) is effective for increasing the internal quantum efficiency IQE. It can be seen from FIG. 3 that the improvement effect of the internal quantum efficiency IQE reaches a saturated state when the Si concentration is about 1.0×10¹⁹/cm³.

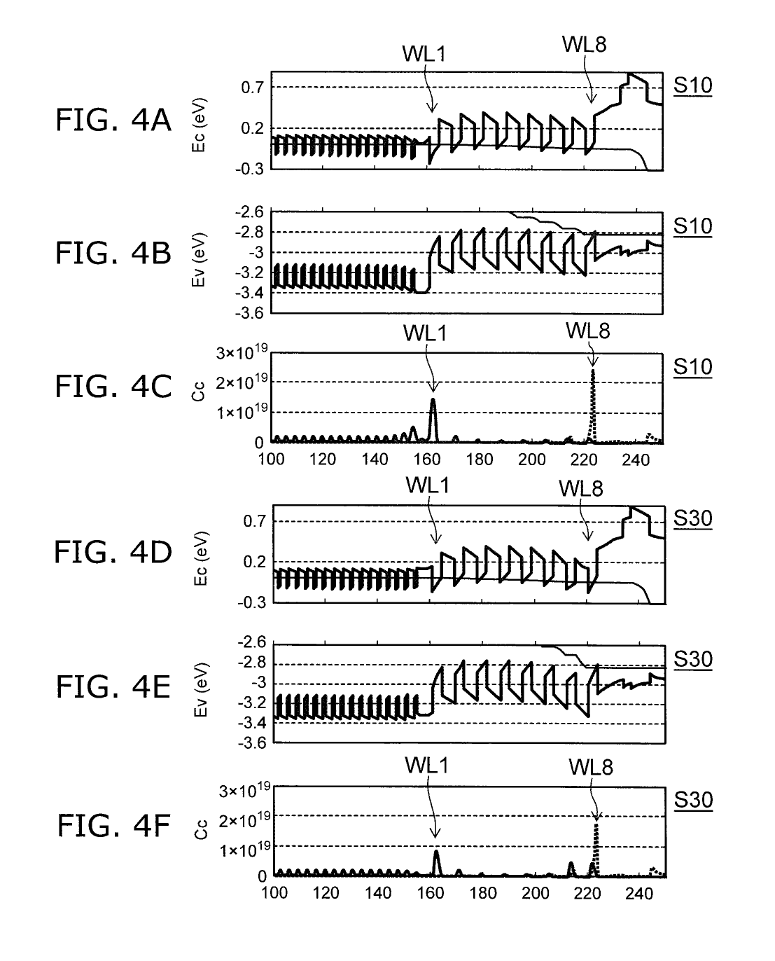

FIG. 4A to FIG. 4F are graphs illustrating characteristics of the semiconductor light emitting element.

FIG. 4A to FIG. 4C correspond to the condition S10 (none of the multiple barrier layers 41 being doped with Si). FIG. 4D to FIG. 4F correspond to the condition S30 (the Si concentration of the barrier layer BL8 being higher than the Si concentration of the first semiconductor layer 10). For the condition S30, the Si concentration of the barrier layer BL8 is 5.0×10¹⁸/cm³.

In these drawings, the horizontal axis is a position z. In FIG. 4A and FIG. 4D, the vertical axis is an energy Ec of the conduction band. In FIG. 4B and FIG. 4E, the vertical axis is the energy of a valence band Ev. FIG. 4C and FIG. 4F are carrier densities Cc of the electrons and the holes. The solid line corresponds to the electrons; and the broken line corresponds to the holes. In these drawings, the current density 3 is 21 (A/cm²).

As shown in FIG. 4A to FIG. 4C, a large amount of electrons is supplied to the well layer WL1. A large amount of holes is supplied to the well layer WL8. The spatial overlap between the electron density and the hole density is small. The effect of increasing the overlap integral is limited because the distributions of the electrons and the holes do not match. As a result, the internal quantum efficiency IQE decreases.

As shown in FIG. 4D to FIG. 4F, a sufficient amount of electrons is supplied to the well layer WL8 as well. The spatial overlap of the electron density and the hole density is large. As a result, the internal quantum efficiency IQE increases.

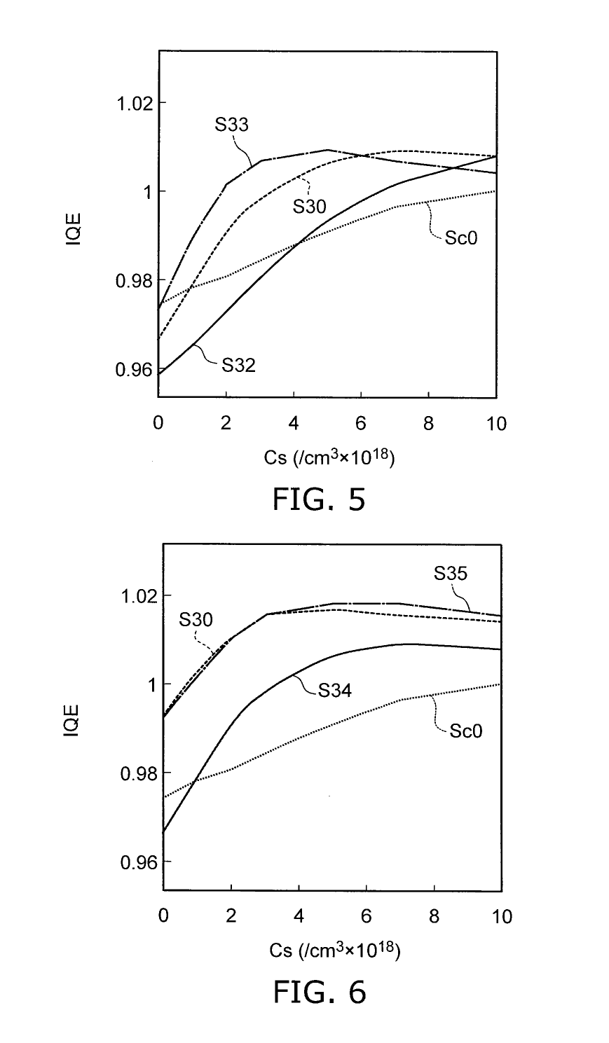

FIG. 5 is a graph illustrating characteristics of the semiconductor light emitting element.

FIG. 5 illustrates simulation results of characteristics for different thicknesses of the multiple barrier layers 41 for the condition S30 (the Si concentration of the barrier layer BL8 being higher than the Si of the first semiconductor layer 10). The horizontal axis is a Si concentration Cs (/cm³). The vertical axis is the internal quantum efficiency IQE.

For a condition S32 shown in FIG. 5, the Si concentration of the barrier layer BL8 is higher than that of the Si of the first semiconductor layer 10; and the thickness of each of the multiple barrier layers 41 is 3.0 nm. For the condition S30, the Si concentration of the barrier layer BL8 is higher than that of the Si of the first semiconductor layer 10; and the thickness of each of the multiple barrier layers 41 is 5.0 nm. For a condition S33, the Si concentration of the barrier layer BL8 is higher than that of the Si of the first semiconductor layer 10; and the thickness of each of the multiple barrier layers 41 is 7.0 nm. The characteristic for the condition Sc0 described above also is illustrated in FIG. 5. For the condition Sc0, the thickness of each of the multiple barrier layers 41 is 5.0 nm. In FIG. 5, the internal quantum efficiency IQE is a relative value for which the maximum value of the internal quantum efficiency for the condition Sc0 is set to 1.

In the example, the Si concentration Cs of the first semiconductor layer 10 is 2.0×10¹⁸/cm³. The current density 3 is 30 (A/cm²). The thickness of each of the multiple well layers 42 is 3.5 nm.

As shown in FIG. 5, the internal quantum efficiency IQE is high when the Si concentration Cs is high for both the conditions S30 and S32. The proportion of the increase of the internal quantum efficiency IQE is different for different thicknesses of the multiple barrier layers 41. The Si concentration Cs at which the internal quantum efficiency IQE peaks is different for different thicknesses of the barrier layers 41.

FIG. 6 is a graph illustrating characteristics of the semiconductor light emitting element.

FIG. 6 shows the results of a simulation of the characteristics for different thicknesses of the multiple well layers 42 for the condition S30. The horizontal axis is the Si concentration Cs (/cm³). The vertical axis is the internal quantum efficiency IQE.

For a condition S34 shown in FIG. 6, the Si concentration of the barrier layer BL8 is higher than the Si concentration of the first semiconductor layer 10; and the thickness of each of the multiple well layers 42 is 3.5 nm. For the condition S30, the Si concentration of the barrier layer BL8 is higher than the Si concentration of the first semiconductor layer 10; and the thickness of each of the multiple well layers 42 is 5.5 nm. For a condition S35, the Si concentration of the barrier layer BL8 is higher than the Si concentration of the first semiconductor layer 10; and the thickness of each of the multiple well layers 42 is 7.5 nm. The characteristic for the condition Sc0 described above also is illustrated in FIG. 6. For the condition Sc0, the thickness of each of the multiple well layers 42 is 3.5 nm. In FIG. 6, the internal quantum efficiency IQE is a relative value for which the maximum value of the internal quantum efficiency for the condition Sc0 is set to 1.

In the example, the Si concentration Cs of the first semiconductor layer 10 is 2.0×10¹⁸/cm³. The current density J is 30 (A/cm²). The thickness of each of the multiple barrier layers 41 is 5.0 nm.

As shown in FIG. 6, the internal quantum efficiency IQE becomes high when the Si concentration Cs becomes high for the conditions S30, S34, and S35. The proportion of the increase of the internal quantum efficiency IQE is different for different thicknesses of the multiple well layers 42.

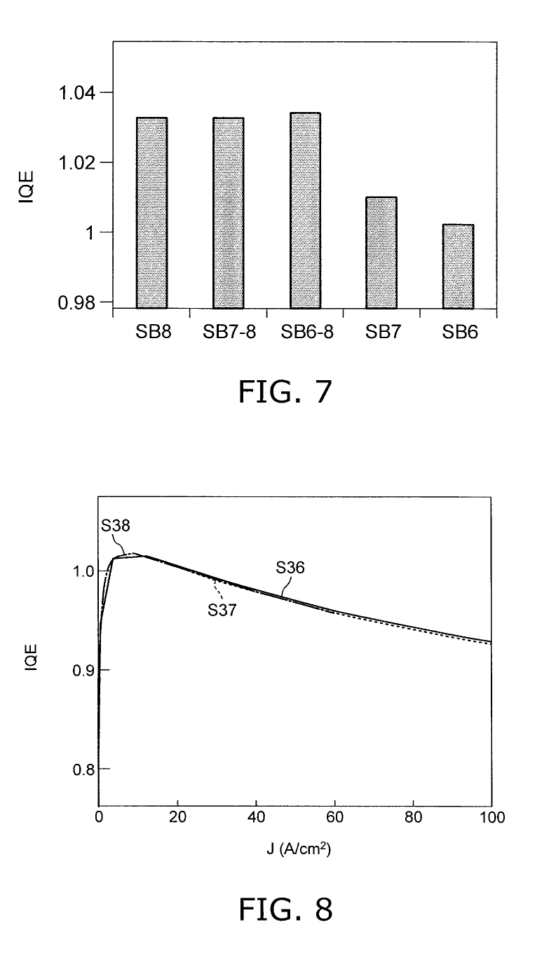

FIG. 7 is a graph illustrating characteristics of the semiconductor light emitting element.

FIG. 7 illustrates the results of a simulation of the characteristics for different positions for the barrier layer having the Si concentration set to be higher than that of the first semiconductor layer 10. The vertical axis of FIG. 7 is the internal quantum efficiency IQE.

In FIG. 7, the Si concentration of the barrier layer BL8 is higher than that of the first semiconductor layer 10 for a condition SB8. For a condition SB7-8, the Si concentrations of the barrier layers BL7 and BL8 are higher than that of the first semiconductor layer 10. For a condition SB6-8, the Si concentrations of the barrier layers BL6 to BL8 are higher than that of the first semiconductor layer 10. For a condition SB7, the Si concentration of the barrier layer BL7 is higher than that of the first semiconductor layer 10. For a condition SB6, the Si concentration of the barrier layer BL6 is higher than that of the first semiconductor layer 10. For these conditions, the barrier layers 41 of which the Si concentrations are not set to be higher than that of the first semiconductor layer 10 are not doped with Si.

As described above, for the condition Sc0, the stacked structure of the c-plane (the polar plane) is applied; and none of the multiple barrier layers 41 are doped with Si. In FIG. 7, the internal quantum efficiency IQE is a relative value for which the internal quantum efficiency for the condition Sc0 is set to be 1.

In the example, the Si concentration of the first semiconductor layer 10 is 2.0×10¹⁸/cm³. In the case where the Si concentration is set to be higher than that of the first semiconductor layer 10, the Si concentration of each of the barrier layers 41 (e.g., BL6 to BL8) is 7.0×10¹⁸/cm³. The Si concentration of the barrier layers not doped with Si is 1.0×10¹⁶/cm³. The current density J is 30 (A/cm²).

It can be seen from FIG. 7 that a high internal quantum efficiency IQE is obtained for the condition SB8, the condition SB7-8, and the condition SB6-8. As described above, in the example, the number of barrier layers 41 is 9. Accordingly, the internal quantum efficiency IQE is high when the Si concentration of the barrier layer BL8 which is the barrier layer of the multiple barrier layers 41 second most proximal to the second semiconductor layer 20 is set to be higher than the Si concentration of the first semiconductor layer 10. A large difference is not seen for the internal quantum efficiencies IQE for the condition SB8, the condition SB7-8, and the condition SB6-8. It is considered to be effective for increasing the internal quantum efficiency IQE to set the Si concentration of at least the barrier layer BL8 to be higher than the Si concentration of the first semiconductor layer 10. In the case where the Si concentration of the barrier layer disposed furthest on the p-side is too high, the p-type semiconductor layer (the second semiconductor layer 20) may contact the n-type semiconductor layer (the barrier layer having the high Si concentration); and the efficiency may decrease.

FIG. 8 is a graph illustrating characteristics of the semiconductor light emitting element.

FIG. 8 illustrates the characteristics for different Si concentrations of the stacked body 30 for the condition S30 (the Si concentration of the barrier layer BL8 being higher than the Si concentration of the first semiconductor layer 10). The horizontal axis is the current density J (A/cm²) injected into the light emitting unit 40. The vertical axis is the internal quantum efficiency IQE.

For a condition S36 shown in FIG. 8, the Si concentration of the barrier layer BL8 is higher than the Si concentration of the first semiconductor layer 10; and the Si concentration of the stacked body 30 is higher than the Si concentration of the first semiconductor layer 10. For a condition S37, the Si concentration of the barrier layer BL8 is higher than the Si concentration of the first semiconductor layer 10; and the stacked body 30 is not doped with Si. For a condition S38, the Si concentration of the barrier layer BL8 is higher than the Si concentration of the first semiconductor layer 10; and the stacked body 30 is not provided. In FIG. 8, the internal quantum efficiency IQE is a relative value for which the internal quantum efficiency for the condition Sc0 is set to 1.

In the example, the Si concentration of the first semiconductor layer 10 is 2.0×10¹⁸/cm³. The Si concentration of the barrier layer BL8 is 7.0×10¹⁸/cm³. For the condition S36, the Si concentration of the stacked body 30 is 2.0×10¹⁸/cm³. For the condition S37, the Si concentration of the stacked body 30 is 1.0×10¹⁶/cm³.

As shown in FIG. 8, there is not a large difference between the amounts that the internal quantum efficiency IQE changes with the current density J for the conditions S36 to S38.

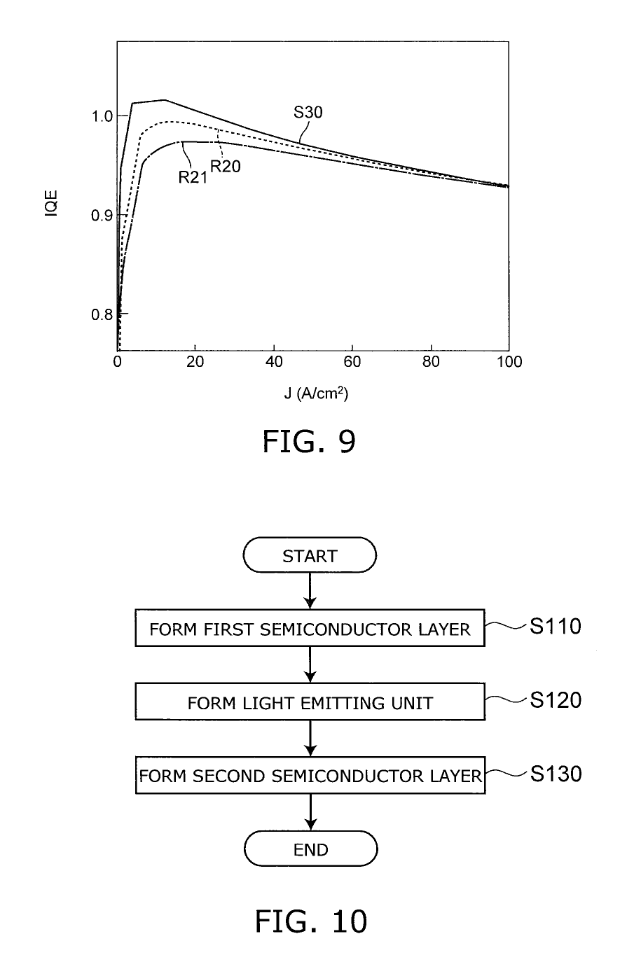

FIG. 9 is a graph illustrating characteristics of the semiconductor light emitting element.

FIG. 9 illustrates the simulation results of the characteristics when the Si concentration of the barrier layer BL2 is modified. The horizontal axis is the current density J (A/cm²) injected into the light emitting unit 40. The vertical axis is the internal quantum efficiency IQE.

For a condition R20 shown in FIG. 9, the number of barrier layers 41 is 3; the number of well layers 42 is 2; and the Si concentration of the barrier layer BL2 is higher than the Si concentration of the first semiconductor layer 10. For a condition R21, the number of barrier layers 41 is 3; the number of well layers 42 is 2; and the barrier layer BL2 is not doped with Si. The Si concentration in the case of not being doped with Si is 1.0×10¹⁶/cm³.

The characteristic for the condition S30 (the number of barrier layers 41 being 9 and the Si concentration of the barrier layer BL8 being higher than the Si concentration of the first semiconductor layer 10) also is illustrated in FIG. 9. In FIG. 9, the internal quantum efficiency IQE is a relative value for which the internal quantum efficiency for the condition Sc0 is set to 1.

In the example, the Si concentration of the first semiconductor layer 10 is 2.0×10¹⁸/cm³. For the condition R20, the Si concentration of the barrier layer BL2 is 7.0×10¹⁸/cm³. The Si concentration of the barrier layer BL8 is 7.0×10¹⁶/cm³.

It can be seen from FIG. 9 that the internal quantum efficiency IQE obtained for the condition R20 is higher than that of the condition R21. In the case where the number of barrier layers 41 is 3 and the number of well layers 42 is 2, the internal quantum efficiency IQE increases when the Si concentration of the barrier layer BL2 is higher than the Si concentration of the first semiconductor layer 10. In such a stacked structure as well, the internal quantum efficiency IQE can be increased by setting the Si concentration of the barrier layer 41 to be higher than the Si concentration of the first semiconductor layer 10.

According to the embodiment, for example, a semiconductor light emitting element having high luminous efficiency for a non-polar or semi-polar multiple quantum well structure is provided.

FIG. 10 is a flowchart illustrating a method for manufacturing the semiconductor light emitting element according to the first embodiment.

The first semiconductor layer 10 is formed on the substrate 5 (step S110). The buffer layer 6 may be formed between the substrate 5 and the first semiconductor layer 10. The first semiconductor layer 10 may have a multilayered structure of the first n-side layer 11 and the second n-side layer 12.

The light emitting layer 40 is formed on the first semiconductor layer 10 (step S120). The light emitting layer 40 includes n+1 barrier layers 41 and n well layers 42. n is an integer not less than 2. The stacked body 30 may be formed between the first semiconductor layer 10 and the light emitting unit 40.

The step of forming the light emitting unit 40 includes a step of forming the barrier layer 41 so that the n-type impurity concentration of at least one barrier layer of the barrier layers BL2 to BLn is higher than the n-type impurity concentration of the first semiconductor layer 10. For example, the n-type impurity concentration of the barrier layer is set to be higher than the n-type impurity concentration of the first semiconductor layer 10 by doping the at least one barrier layer of the barrier layers BL2 to BLn with Si. In other words, the light emitting unit 40 includes the first barrier layer, the second barrier layer that is provided on the first barrier layer and includes an n-type impurity having the second concentration higher than the n-type impurity concentration (the first concentration) of the first semiconductor layer 10, the third barrier layer that is provided on the second barrier layer, the first well layer that is provided between the first barrier layer and the second barrier layer, and the second well layer that is provided between the second barrier layer and the third barrier layer. Such a light emitting unit is formed.

The second semiconductor layer 20 is formed on the light emitting unit 40 (step S130). After forming the second semiconductor layer 20, the first electrode 50 and the second electrode 60 are formed.

According to the embodiment, a semiconductor light emitting element having high luminous efficiency and a method for manufacturing the semiconductor light emitting element are provided.

In the specification, “nitride semiconductor” includes all compositions of semiconductors of the chemical formula B_{α}In_{β}Al_{γ}Ga_{1-α-β-γ}N (0≦α≦1, 0≦β≦1, 0≦γ≦1, and α+β+γ≦1) for which the composition ratios α, β, and γ are changed within the ranges respectively. “Nitride semiconductor” further includes group V elements other than N (nitrogen) in the chemical formula recited above, various elements added to control various properties such as the conductivity type and the like, and various elements included unintentionally.

Hereinabove, embodiments of the invention are described with reference to specific examples. However, the invention is not limited to these specific examples. For example, one skilled in the art may similarly practice the invention by appropriate selections from known art including various modifications made by one skilled in the art in regard to the configurations, the sizes, the material properties, the arrangements, etc., of specific configurations of components included in the semiconductor light emitting element such as the first semiconductor layer, the second semiconductor layer, the light emitting unit, the well layer, the barrier layer, the first electrode, the second electrode, etc.; and such practice is within the scope of the invention to the extent that similar effects can be obtained.

Further, any two or more components of the specific examples may be combined within the extent of technical feasibility and are included in the scope of the invention to the extent that the purport of the invention is included.

Moreover, all semiconductor light emitting elements and methods for manufacturing semiconductor light emitting elements practicable by an appropriate design modification by one skilled in the art based on the semiconductor light emitting elements and the methods for manufacturing semiconductor light emitting elements described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting element, comprising:
a first semiconductor layer including an n-type impurity having a first concentration;
a second semiconductor layer including a p-type impurity; and
a light emitting unit provided between the first semiconductor layer and the second semiconductor layer, the light emitting unit including
a first barrier layer,
a second barrier layer provided between the first barrier layer and the second semiconductor layer, the second barrier layer including an n-type impurity having a second concentration higher than the first concentration,
a third barrier layer provided between the second barrier layer and the second semiconductor layer,
a first well layer provided between the first barrier layer and the second barrier layer, and
a second well layer provided between the second barrier layer and the third barrier layer,
a plane including a boundary between the first barrier layer and the first well layer intersecting a plane including a (0001) plane of the first semiconductor layer.

2. The element according to claim 1, wherein an angle between the boundary and the (0001) plane is not less than 15 degrees and not more than 165 degrees.

3. The element according to claim 1, wherein the boundary is tilted with respect to the (0001) plane.

4. The element according to claim 1, wherein the second concentration is not less than 2.0×10¹⁸ per cubic centimeter.

5. The element according to claim 1, wherein the second concentration is not less than 5.0×10¹⁸ per cubic centimeter.

6. The element according to claim 1, wherein a thickness of the second barrier layer is not less than 3.0 nanometers and not more than 7.0 nanometers.

7. The element according to claim 1, wherein the first barrier layer and the third barrier layer have thicknesses not less than 3.0 nanometers and not more than 7.0 nanometers.

8. The element according to claim 1, wherein the first well layer and the second well layer have thicknesses not less than 3.5 nanometers and not more than 7.5 nanometers.

9. A method for manufacturing a semiconductor light emitting element, comprising:
forming a first semiconductor layer on a substrate, the first semiconductor layer including an n-type impurity having a first concentration;
forming a light emitting unit on the first semiconductor layer, the light emitting unit including a first barrier layer, a second barrier layer provided on the first barrier layer, a third barrier layer provided on the second barrier layer, a first well layer provided between the first barrier layer and the second barrier layer, and a second well layer provided between the second barrier layer and the third barrier layer, the second barrier layer including an n-type impurity having a second concentration higher than the first concentration; and
forming a second semiconductor layer on the light emitting unit, the second semiconductor layer including a p-type impurity,
a plane including a boundary between the first barrier layer and the first well layer intersecting a plane including a (0001) plane of the first semiconductor layer.

10. The method according to claim 9, wherein an angle between the boundary and the (0001) plane is not less than 15 degrees and not more than 165 degrees.

11. The method according to claim 9, wherein the boundary is tilted with respect to the (0001) plane.

12. The method according to claim 9, wherein the second concentration is not less than 2.0×10¹⁸ per cubic centimeter.

13. The method according to claim 9, wherein the second concentration is not less than 5.0×10¹⁸ per cubic centimeter.

14. The method according to claim 9, wherein a thickness of the second barrier layer is not less than 3.0 nanometers and not more than 7.0 nanometers.

15. The method according to claim 9, wherein the first barrier layer and the third barrier layer have thicknesses not less than 3.0 nanometers and not more than 7.0 nanometers.

16. The method according to claim 9, wherein the first well layer and the second well layer have thicknesses not less than 3.5 nanometers and not more than 7.5 nanometers.
